(19) United States
(12) Patent Application Publication
(10) Pub. No.: US 2023/0062206 A1
(43) Pub. Date: Mar. 2, 2023

(54) DETERMINING SUBSTRATE PROFILE PROPERTIES USING MACHINE LEARNING

(71) Applicant: APPLIED MATERIALS, INC., Santa Clara, CA (US)

(72) Inventors: Thomas Li, Santa Clara, CA (US); Upendra V. Ummethala, Cupertino, CA (US); Blake Erickson, Gilroy, CA (US); Prashanth Kumar, Union City, CA (US); Michael Kutney, Santa Clara, CA (US); Steven Trey Tindel, Austin, TX (US); Zhaozhao Zhu, Milpitas, CA (US)

(21) Appl. No.: 18/046,872

(22) Filed: Oct. 14, 2022

Related U.S. Application Data
(63) Continuation-in-part of application No. 17/379,707, filed on Jul. 19, 2021.
(60) Provisional application No. 63/055,244, filed on Jul. 22, 2020.

(51) Int. Cl. G03F 7/20

(52) U.S. Cl. CPC G03F 7/705; G03F 7/70625

(57) ABSTRACT

Spectral data associated with a first prior substrate and/or a second prior substrate is obtained. A metrology measurement value associated with the first portion of the first prior substrate is determined based on one or more metrology measurement values measured for at least one of a second portion of the first prior substrate or a third portion of a second prior substrate. Training data for training a machine learning model to predict metrology measurement values of a current substrate is generated. Generating the training data includes generating a first training input including the spectral data associated with the first prior substrate and generating a first target output for the first training input, the first target output including the determined metrology measurement value associated with the first portion of the first prior substrate. The training data is provided to train the machine learning model.

### RELATED APPLICATION

This application is a continuation-in-part (CIP) application of co-pending U.S. patent application Ser. No. 17/379,707, filed Jul. 19, 2021, titled “Determining Substrate Profile Properties Using Machine Learning,” which claims the benefit of U.S. Provisional Patent Application 63/055,244, filed Jul. 22, 2020, the entire content of which is incorporated by reference herein.

### TECHNICAL FIELD

Embodiments of the present disclosure relate, in general, to manufacturing systems and more particularly to determining profile properties of a substrate.

### BACKGROUND

Substrate profile properties are metrics that can be used for evaluating a substrate during or after processing at a manufacturing system. Typically, substrate profile properties are measured using a metrology system that is separate from a manufacturing tool used at the manufacturing system. In order to measure a substrate profile property, a substrate is removed from the manufacturing tool and measured at the metrology system. After the measurement for the substrate is obtained at the metrology system, the substrate is returned to the manufacturing tool for further processing. Removing the substrate from the manufacturing tool to measure the substrate at the metrology system is a costly operation that results in a decrease in overall process efficiency. Due to the cost of removing the substrate from the manufacturing tool, few substrates that are processed at the manufacturing system are measured, resulting in a low sampling rate of all substrates processed at the manufacturing system. The measurements generated for these few substrates are used to make process decisions for other substrates processed at the manufacturing tool that are not measured. The process decisions made based on the measurements generated for a few substrates can result in substrate defects and, in some instances, damage to equipment at the manufacturing system.

### SUMMARY

Some of the embodiments described cover a method for training a machine learning model to predict metrology measurements of a current substrate being processed at a manufacturing system. The method including obtaining spectral data associated with a first portion of a first prior substrate at a manufacturing system and at least one of a second portion of the first prior substrate or a third portion of a second prior substrate at the manufacturing system. The method further includes identifying one or more metrology measurement values obtained for the at least one of the second portion of the first prior substrate or the third portion of the second prior substrate. The method further includes determining a metrology measurement value associated with the first portion of the first prior substrate based on the identified one or more metrology measurement values. The method further includes generating training data for training a machine learning model to predict metrology measurement values of a current substrate at the manufacturing system. Generating the training data includes generating a first training input including the spectral data associated with the first portion of the first prior substrate and generating a first target output for the first training input, the first target output including the determined metrology measurement value associated with the first portion of the first prior substrate. The method further includes providing the data to train the machine learning model on (i) a set of training inputs including the first training input, and (ii) a set of target outputs including the first target output.

In some embodiments, an apparatus includes a memory and a processing device coupled to the memory. The processing device is to perform operations including obtaining spectral data associated with a first portion of a first prior substrate at a manufacturing system and at least one of a second portion of the first prior substrate or a third portion of a second prior substrate at the manufacturing system. The operations further include identifying one or more metrology measurement values obtained for the at least one of the second portion of the first prior substrate or the third portion of the second prior substrate. The operations further include determining a metrology measurement value associated with the first portion of the first prior substrate based on the identified one or more metrology measurement values. The operations further include generating training data for training a machine learning model to predict metrology measurement values of a current substrate at the manufacturing system. Generating the training data includes generating a first training input including the spectral data associated with the first portion of the first prior substrate and generating a first target output for the first training input, the first target output including the determined metrology measurement value associated with the first portion of the first prior substrate. The operations further include providing the data to train the machine learning model on (i) a set of training inputs including the first training input, and (ii) a set of target outputs including the first target output.

In some embodiments, a non-transitory computer readable storage medium includes instructions that, when executed by a processing device, cause the processing device to perform operations including obtaining spectral data associated with a first portion of a first prior substrate at a manufacturing system and at least one of a second portion of the first prior substrate or a third portion of a second prior substrate at the manufacturing system. The operations further include identifying one or more metrology measurement values obtained for the at least one of the second portion of the first prior substrate or the third portion of the second prior substrate. The operations further include determining a metrology measurement value associated with the first portion of the first prior substrate based on the identified one or more metrology measurement values. The operations further include generating training data for training a machine learning model to predict metrology measurement values of a current substrate at the manufacturing system. Generating the training data includes generating a first training input including the spectral data associated with the first portion of the first prior substrate and generating a first target output for the first training input, the first target output including the determined metrology measurement value associated with the first portion of the first prior substrate. The operations further include providing the data to train the machine learning model on (i) a set of training inputs including the first training input, and (ii) a set of target outputs including the first target output.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts an illustrative computer system architecture, according to aspects of the present disclosure.

FIG. 2 is a flow chart of a method for training a machine learning model, according to aspects of the present disclosure.

FIG. 3 is a top schematic view of an example manufacturing system, according to aspects of the present disclosure.

FIG. 4 is a cross-sectional schematic side view of a substrate measurement subsystem, according to aspects of the present disclosure.

FIG. 5 illustrates spectral data collected for a substrate, according to aspects of the present disclosure.

FIG. 6 is a flow chart of a method for estimating a metrology value for a profile of a substrate using a machine learning model, according to aspects of the present disclosure.

FIGS. 7A-C illustrate an example GUI for providing an indication of an estimated metrology value for a profile of a substrate, according to aspects of the present disclosure.

FIG. 8 is a flow chart of a method for generating training data for training a machine learning model, according to aspects of the present disclosure.

FIG. 9 illustrates an example of determining metrology measurement values for a substrate, according to aspects of the present disclosure.

FIG. 10 is a flow chart of a method for determining metrology measurement values for substrates at a manufacturing system, according to aspects of the present disclosure.

FIG. 11 is a flow chart of another method for determining metrology measurement values for substrates at a manufacturing system, according to aspects of the present disclosure.

FIG. 12 depicts a block diagram of an illustrative computer system operating in accordance with one or more aspects of the present disclosure.

### DETAILED DESCRIPTION OF EMBODIMENTS

Properties of a substrate profile (e.g., a surface including three-dimensional (3D) structures, a surface including non-3D structures, etc.) are important for an overall performance of a final, processed substrate and/or an overall production yield of substrates at the manufacturing system. In some instances, properties of a substrate profile may be monitored by the generation of metrology measurements for the substrate during or after a substrate process at the manufacturing system. A metrology measurement can include an etch rate (i.e., a rate at which a certain material deposited on the surface of the substrate is etched in a processing chamber), an etch rate uniformity (i.e., a variation of an etch rate at two or more portions of the surface of the substrate), a critical dimension (i.e., a unit of measurement for measuring a dimension of elements of a substrate, such as lines, columns, openings, spaces, etc.), critical dimension uniformity (i.e., a variation of critical dimensions across a surface of a substrate), edge to edge placement error (EPE) (i.e., a difference between the intended and resulting features included on a surface of a substrate), and so forth.

Implementations described herein provide methods and systems for training and using a machine learning model to predict metrology measurements of a current substrate being processed at a manufacturing system. The machine learning model may be trained using historical spectral data collected for various portions of a prior substrate processed at the manufacturing system. Spectral data may correspond to an intensity (i.e., a strength of amount of energy) of a detected wave of energy for each given wavelength of a detected wave of energy. In some embodiments, spectral data may be generated at a substrate measurement subsystem included within the measurement system. In other or similar embodiments, spectral data may be generated at another portion of the manufacturing system, such as at a processing chamber. The historical spectral data may be provided as a training input for the machine learning model. The machine learning may also be trained using historical non-spectral data collected for various portions of the prior substrate. For example, eddy current data, capacitance data, and so forth, may be generated for the substrate and provided as training input for the machine learning model.

In some embodiments, the machine learning model may be further trained using historical spectral data indicating the portion of the prior substrate associated with the historical spectral data. Positional data may refer to a position and/or an orientation of the substrate when the spectral data for a portion of the substrate was measured (i.e., at the substrate measurement subsystem or at the processing chamber). In some embodiments, the historical positional data may also be provided as a training input for the machine learning model.

The machine learning model may be further trained using historical metrology measurements collected for the prior substrate processed at the manufacturing system. In some embodiments, the historical metrology measurement can be received from a metrology measurement system that is separate from the manufacturing system (referred to as an external metrology measurement system). In other or similar embodiments, the historical metrology measurement can be received from a client device of the manufacturing system. Historical metrology measurements may be generated for each substrate processed at the manufacturing system. The historical metrology measurements may be provided as target outputs for the machine learning model.

In some embodiments, training data used for training the machine learning model can be generated based on metrology measurements that are predicted or otherwise determined for prior substrates at the manufacturing system. In one example, spectral data can be collected for a first portion of a first prior substrate at the manufacturing system, in accordance with embodiments described herein. Spectral data can also be collected for a second portion of the first prior substrate and/or for a third portion of a second prior substrate at the manufacturing system. In some embodiments, metrology measurements can be collected for the second portion of the first prior substrate and/or for the third portion of the second prior substrate (e.g., but not for the first portion of the first prior substrate). An indication of coordinates (e.g., Cartesian coordinates, etc.) for the first portion of the first prior substrate and the second portion of the first prior substrate and/or the third portion of the second prior substrate can be provided as input to a function. The metrology measurement values measured for the second portion of the first prior substrate and/or the third portion of the second prior substrate can also be provided as input to the function. In some embodiments, the function can include a linear interpolation function, an extrapolation function, a nearest-neighbor interpolation function, or a Euclidean distance function. The function can provide, as an output, an indication of one or more metrology measurement values of a substrate. The metrology measurement value for the first portion of the first prior substrate can be determined based on one or more outputs of the function.

In additional or alternative embodiments, the spectral data collected for the first portion can be provided as input to an additional machine learning model. The spectral data can be provided with contextual data associated with the first prior substrate, in some embodiments. The additional machine learning model can be trained to predict, based on spectral data and contextual data for a prior substrate at the manufacturing system, one or more metrology measurement values for prior substrates. Contextual data can include an indication of the first coordinates associated with the first portion of the first prior substrate, a substrate process performed for the first prior substrate, a time period during which the substrate process was performed for the first prior substrate, a time period during which the spectral data was collected for the first prior substrate, an indication of one or more types of equipment used to perform the substrate process, and so forth. One or more outputs of the additional machine learning model can include metrology data including one or more sets of metrology measurement values and an indication of a level of confidence that a respective set of metrology measurement values corresponds to the first portion of the first prior substrate. A set of metrology measurement values having a level of confidence that satisfies a confidence criterion (e.g., exceeds a threshold level of confidence, etc.) is identified. The set of metrology measurement values can include the metrology measurement value for the first portion of the first prior substrate. Further details regarding predicting or otherwise determining metrology measurements for prior substrates at the manufacturing system are provided herein.

The machine learning model, once trained, may be used to predict metrology measurements of a current substrate being processed at the manufacturing system. Spectral data may be generated for the current substrate (i.e., at the substrate measurement subsystem or at the processing chamber) during or after a substrate process at the manufacturing system. The spectral data may be provided to the trained machine learning model as an input. In some embodiments, positional data may also be generated for the current substrate, where the positional data is associated with the spectral data. In such embodiments, the positional data may be provided to the trained machine learning model with the spectral data as another input. The trained machine learning model can produce one or more outputs including a metrology measurement for a prior substrate processed at the manufacturing system and a level of confidence that the current substrate being processed at the manufacturing system is associated with the metrology measurement for the prior substrate. A metrology measurement for the current substrate being processed at the manufacturing system may be extracted from the one or more outputs. In some embodiments, the metrology measurement for the current substrate can be provided to a user of the manufacturing system via a graphical user interface (GUI) displayed at a client device of the manufacturing system.

Aspects of the present disclosure address the above noted deficiencies conventional technology by providing systems and methods for training and using a machine learning model to predict metrology measurement values for a substrate being processed at a manufacturing system. Spectral data and/or non-spectral data can be generated for each substrate at various portions of the manufacturing system (i.e., the substrate measurement subsystem, a processing chamber, etc.) and provided to the trained machine learning model to determine a metrology measurement value for a substrate while the substrate remains within the manufacturing system. By determining the metrology measurement value for the substrate while the substrate remains within the manufacturing system, the substrate is not removed from the manufacturing system during a substrate process, thereby improving overall system throughput. Further, because spectral data and/or spectral can be generated for each substrate being processed at the manufacturing system, a metrology measurement value can be generated for each substrate, resulting in a high sampling rate of all substrates processed at the manufacturing system. Process modifications for a substrate may be made at the manufacturing system based on a metrology measurement value for the substrate, rather than based on a metrology measurement value for another substrate, thus increasing a likelihood that a process modification will result in successfully processing the substrate. As a result, a number of defects that occur within the manufacturing system will decrease, thereby improving overall system efficiency. In addition, a deviation from an expected metrology measurement value for the substrate can be detected and an error protocol (e.g., transmitting an error message to an operator of the manufacturing system, stopping operations at the manufacturing system, etc.) can be initiated based on the detected deviation, thus preventing unnecessary damage to the substrate and/or the manufacturing system.

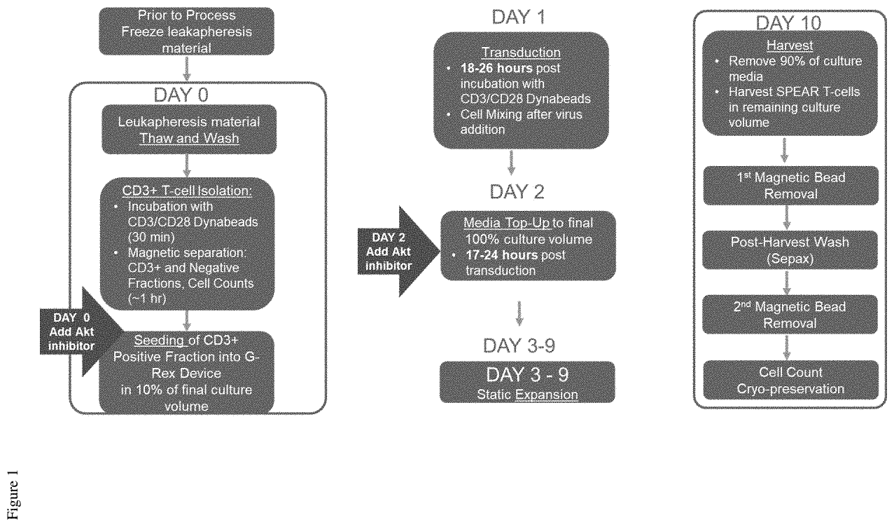

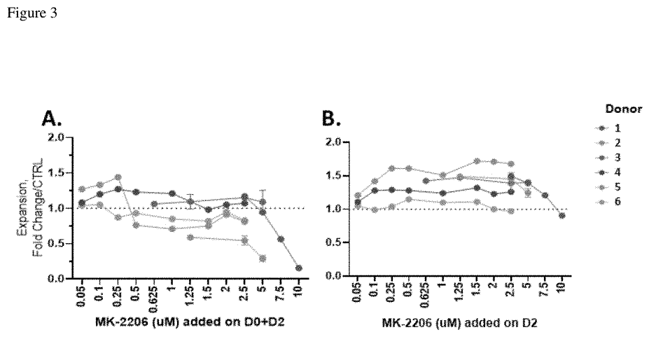

FIG. 1 depicts an illustrative computer system architecture 100, according to aspects of the present disclosure. In some embodiments, computer system architecture 100 may be included as part of a manufacturing system for processing substrates, such as manufacturing system 300 of FIG. 3. Computer system architecture 100 includes a client device 120, manufacturing equipment 124, metrology equipment 128, a predictive server 112 (e.g., to generate predictive data, to provide model adaptation, to use a knowledge base, etc.), and a data store 140. The predictive server 112 may be part of a predictive system 110. The predictive system 110 may further include server machines 170 and 180. The manufacturing equipment 124 may include sensors 125 configured to capture data for a substrate being processed at the manufacturing system. In some embodiments, the manufacturing equipment 124 and sensors 126 may be part of a sensor system that includes a sensor server (e.g., field service server (FSS) at a manufacturing facility) and sensor identifier reader (e.g., front opening unified pod (FOUP) radio frequency identification (RFID) reader for sensor system). In some embodiments, metrology equipment 128 may be part of a metrology system that includes a metrology server (e.g., a metrology database, metrology folders, etc.) and metrology identifier reader (e.g., FOUP RFID reader for metrology system).

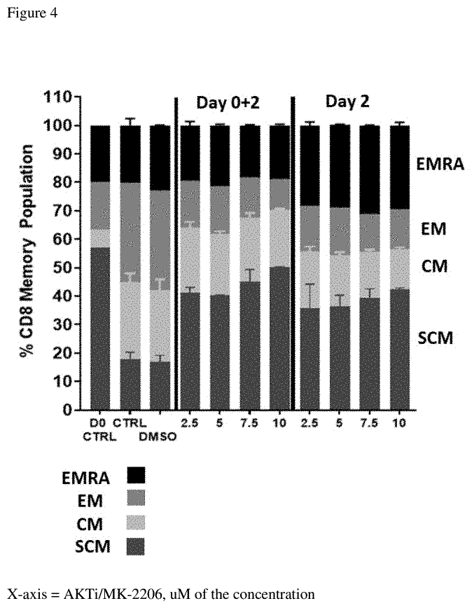

Manufacturing equipment 124 may produce products following a recipe or performing runs over a period of time. Manufacturing equipment 124 may include a substrate measurement subsystem that includes one or more sensors 126 configured to generate spectral data and/or positional data for a substrate embedded within the substrate measurement subsystem. Sensors 126 that are configured to generate spectral data (herein referred to as spectra sensing components) may include reflectometry sensors, ellipsometry sensors, thermal spectra sensors, capacitive sensors, and so forth. In some embodiments, spectra sensing components may be included within the substrate measurement subsystem or another portion of the manufacturing system. One or more sensors 126 (e.g., eddy current sensors, etc.) may also be configured to generate non-spectral data for the substrate. Further details regarding manufacturing equipment 124 and the substrate measurement subsystem are provided with respect to FIG. 3 and FIG. 4.

In some embodiments, sensors 126 may provide sensor data associated with manufacturing equipment 124. Sensor data may include a value of one or more of temperature (e.g., heater temperature), spacing (SP), pressure, high frequency radio frequency (HFRF), voltage of electrostatic chuck (ESC), electrical current, flow, power, voltage, etc. Sensor data may be associated with or indicative of manufacturing parameters such as hardware parameters, such as settings or components (e.g., size, type, etc.) of the manufacturing equipment 124, or process parameters of the manufacturing equipment 124. The sensor data may be provided while the manufacturing equipment 124 is performing manufacturing processes (e.g., equipment readings when processing products). The sensor data 142 may be different for each substrate.

Metrology equipment 128 may provide metrology data associated with substrates (e.g., wafers, etc.) processed by manufacturing equipment 124. The metrology data may include a value of one or more of film property data (e.g., wafer spatial film properties), dimensions (e.g., thickness, height, etc.), dielectric constant, dopant concentration, density, defects, etc. In some embodiments, the metrology data may further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data may be of a finished or semi-finished product. The metrology data may be different for each substrate.

The client device 120 my include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc.

In some embodiments, the metrology data may be received from the client device 120. Client device 120 can display a graphical user interface (GUI), where the GUI enables the user to provide, as input, metrology measurement values for substrates processed at the manufacturing system.

Data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may store spectral data, non-spectral data, metrology data, and predictive data. Spectral data may include historical spectral data (e.g., spectral data generated for a previous substrate processed at the manufacturing system) and/or current spectra (spectral data generated for a current substrate being processed at the manufacturing system. Current spectral data may be data for which predictive data is generated. Although embodiments of the present disclosure reference spectral data for training a machine learning model, it should be noted that embodiments of the present disclosure can also include non-spectral data used to train the machine learning model. In some embodiments, metrology data can include historical metrology data (e.g., metrology measurement values for a prior substrate processed at the manufacturing system). The data store 140 may also store contextual data associated with a substrate being processed at the manufacturing system (e.g., recipe name, recipe step number, preventive maintenance indicator, operator, etc.).

In some embodiments, data store 140 may be configured to store data that is not accessible to a user of the manufacturing system. For example, spectral data, non-spectral data, and/or positional data obtained for a substrate being processed at the manufacturing system may not be accessible to a user of the manufacturing system. In some embodiments, all data stored at data store 140 may be inaccessible by a user (e.g., an operator) of the manufacturing system. In other or similar embodiments, a portion of data stored at data store 140 may be inaccessible by the user while another portion of data stored at data store 140 may be accessible by the user. In some embodiments, one or more portions of data stored at data store 140 may be encrypted using an encryption mechanism that is unknown to the user (e.g., data is encrypted using a private encryption key). In other or similar embodiments, data store 140 may include multiple data stores where data that is inaccessible to the user is stored in one or more first data stores and data that is accessible to the user is stored in one or more second data stores.

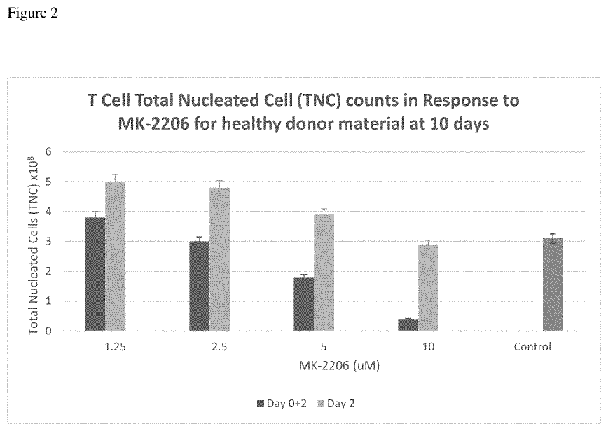

In some embodiments, predictive system 110 includes server machine 170 and server machine 180. Server machine 170 includes a training set generator 172 that is capable of generating training data sets (e.g., a set of data inputs and a set of target outputs) to train, validate, and/or test a machine learning model 190. Some operations of training set generator 172 are described in detail below with respect to FIGS. 2 and 8-11. In some embodiments, the training set generator 172 may partition the training data into a training set, a validating set, and a testing set. In some embodiments, the predictive system 110 generates multiple sets of training data. For example a first set of training data may correspond to a first type of spectral data (e.g., reflectometry spectral data) and a second set of training data may correspond to a second type of spectral data (ellipsometry spectral data).

Server machine 180 may include a training engine 182, a validation engine 184, a selection engine 185, and/or a testing engine 186. An engine may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. Training engine 182 may be capable of training a machine learning model 190. The machine learning model 190 may refer to the model artifact that is created by the training engine 182 using the training data that includes training inputs and corresponding target outputs (correct answers for respective training inputs). The training engine 182 may find patterns in the training data that map the training input to the target output (the answer to be predicted), and provide the machine learning model 190 that captures these patterns. The machine learning model 190 may use one or more of support vector machine (SVM), Radial Basis Function (RBF), clustering, supervised machine learning, semi-supervised machine learning, unsupervised machine learning, k-nearest neighbor algorithm (k-NN), linear regression, random forest, neural network (e.g., artificial neural network), etc.

The validation engine 184 may be capable of validating a trained machine learning model 190 using a corresponding set of features of a validation set from training set generator 172. The validation engine 184 may determine an accuracy of each of the trained machine learning models 190 based on the corresponding sets of features of the validation set. The validation engine 184 may discard a trained machine learning model 190 that has an accuracy that does not meet a threshold accuracy. In some embodiments, the selection engine 185 may be capable of selecting a trained machine learning model 190 that has an accuracy that meets a threshold accuracy. In some embodiments, the selection engine 185 may be capable of selecting the trained machine learning model 190 that has the highest accuracy of the trained machine learning models 190.

The testing engine 186 may be capable of testing a trained machine learning model 190 using a corresponding set of features of a testing set from training set generator 172. For example, a first trained machine learning model 190 that was trained using a first set of features of the training set may be tested using the first set of features of the testing set. The testing engine 186 may determine a trained machine learning model 190 that has the highest accuracy of all of the trained machine learning models based on the testing sets.

Predictive server 112 includes a predictive component 114 that is capable of providing spectral data and/or non-spectral data for a portion of a current substrate being processed at a manufacturing system as input to trained machine learning model 190 and running trained machine learning model 190 on the input to obtain one or more outputs. As described in detail below with respect to FIG. 4, in some embodiments, predictive component 114 is also capable of extracting data from the output of the trained machine learning model 190 and using the confidence data to estimate a metrology measurement for a portion of the substrate.

The confidence data may include or indicate a level of confidence that a metrology value corresponds one or more properties of a substrate associated with current spectral data and/or spectral data. In one example, the level of confidence is a real number between 0 and 1 inclusive, where 0 indicates no confidence that the metrology value corresponds to one or more properties of the substrate associated with the current spectral data and 1 indicates absolute confidence that the metrology value corresponds to one or more properties of the substrate associated with the current spectral data. In some embodiments, the system 100 may use predictive system 110 to determine metrology values for a substrate being processed at the manufacturing system instead of using the metrology equipment 128 to determine measured metrology values.

The client device 120, manufacturing equipment 124, sensors 126, metrology equipment 128, predictive server 112, data store 140, server machine 170, and server machine 180 may be coupled to each other via a network 130. In some embodiments, network 130 is a public network that provides client device 120 with access to predictive server 112, data store 140, and other publically available computing devices. In some embodiments, network 130 is a private network that provides client device 120 access to manufacturing equipment 124, metrology equipment 128, data store 140, and other privately available computing devices. Network 130 may include one or more wide area networks (WANs), local area networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

It should be noted that in some other implementations, the functions of server machines 170 and 180, as well as predictive server 112, may be provided by a fewer number of machines. For example, in some embodiments, server machines 170 and 180 may be integrated into a single machine, while in some other or similar embodiments, server machines 170 and 180, as well as predictive server 112, may be integrated into a single machine.

In general, functions described in one implementation as being performed by server machine 170, server machine 180, and/or predictive server 112 can also be performed on client device 120. In addition, the functionality attributed to a particular component can be performed by different or multiple components operating together.

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

FIG. 2 is a flow chart of a method 200 for training a machine learning model, according to aspects of the present disclosure. Method 200 is performed by processing logic that may include hardware (circuitry, dedicated logic, etc.), software (such as is run on a general purpose computer system or a dedicated machine), firmware, or some combination thereof. In one implementation, method 200 may be performed by a computer system, such as computer system architecture 100 of FIG. 1. In other or similar implementations, one or more operations of method 200 may be performed by one or more other machines not depicted in the figures. In some aspects, one or more operations of method 200 may be performed by training set generator 172 of server machine 170.

For simplicity of explanation, the methods are depicted and described as a series of acts. However, acts in accordance with this disclosure may occur in various orders and/or concurrently, and with other acts not presented and described herein. Furthermore, not all illustrated acts may be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 210, processing logic initializes a training set T to an empty set (e.g., { }). At block 220, processing logic receives data (e.g., spectral data, non-spectral data, etc.) for a substrate being processed at a manufacturing system. In some embodiments, the data may be received from a substrate measurement subsystem integrated with the manufacturing system. In other or similar embodiments, the data may be received from one or more sensors at another portion of the manufacturing system (e.g., a processing chamber, a load lock, a transfer chamber, etc.). In should be noted that in some other implementations, data may be received in some other manner, and may not be received from a portion of the manufacturing system.

At block 230, processing logic optionally receives positional data for the substrate being processed at the manufacturing system. In some embodiments, the positional data may be received from the substrate measurement subsystem with the data. In other or similar embodiments, the data may be received from one or more sensors at another portion of the manufacturing system. It should be noted that in some other implementations, the positional data may be received in some other manner, and may not be received from a portion of the manufacturing system.

At block 240, processing logic receives one or more metrology measurements for the substrate. A metrology measurement can be obtained for a substrate at a metrology measurement system that is separate from the manufacturing system (i.e., an external metrology measurement system). In some embodiments, the external metrology measurement system may be communicatively coupled to the manufacturing system (e.g., by network 130 of FIG. 1). In such embodiments, processing logic can receive the one or more metrology measurements for the substrate from the external metrology measurement system via the network. In other embodiments, the metrology measurements can be generated at the external metrology measurement system and provided to manufacturing system via a client device. For example, a client device connected to the manufacturing system can provide a graphical user interface (GUI) to a user of the manufacturing system (e.g., an operator). After the substrate is measured at the external metrology sub-system, the user can provide the metrology measurement value to the client device via the GUI. Responsive to receiving the provided metrology measurement value, the client device can store the metrology measurement value at a data store, such as data store 140 of the manufacturing system.

In some embodiments, processing logic can determine a metrology measurement value for a portion of a substrate at the manufacturing system based on metrology measurement values collected for other portions of the substrate and/or for other substrates. Further details regarding determining such metrology measurement values and generating training data using such metrology measurement values are described with respect to FIGS. 8-11 below.

At block 250, processing logic generates an input/output mapping. The input/output mapping refers to the training input that includes or is based on data for the substrate, and the target output for the training input, where the target output identifies a metrology measurement value for the substrate, and where the training input is associated with (or mapped to) the target output. At block 260, processing logic adds the input/output mapping to the training set T.

At block 270, processing logic determines whether the training set, T, includes a sufficient amount of training data to train a machine learning model. It should be noted that in some implementations, the sufficiency of training set T may be determined based simply on the number of input/output mappings in the training set, while in some other implementations, the sufficiency of training set T may be determined based on one or more other criteria (e.g., a measure of diversity of the training examples, etc.) in addition to, or instead of, the number of input/output mappings. Responsive to determining the training set, T, includes a sufficient amount of training data to train the machine learning model, processing logic provides the training set, T, to train the machine learning model. Responsive to determining the training set does not include a sufficient amount of training data to train the machine learning model, method 200 returns to block 220.

At block 280, processing logic provides the training set T to train the machine learning model. In one implementation, the training set T is provided to training engine 182 of server machine 180 to perform the training. In the case of a neural network, for example, input values of a given input/output mapping (e.g., spectral data for a previous substrate) are input to the neural network, and output values of the input/output mapping are stored in the output nodes of the neural network. The connection weights in the neural network are then adjusted in accordance with a learning algorithm (e.g., backpropagation, etc.), and the procedure is repeated for the other input/output mappings in the training set T. After block 280, machine learning model 190 can be used to estimate metrology values for future substrates processed at the manufacturing system (for example, in accordance with method 600 of FIG. 6 described below).

FIG. 3 is a top schematic view of an example manufacturing system 300, according to aspects of the present disclosure. Manufacturing system 300 may perform one or more processes on a substrate 302. Substrate 302 may be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 300 may include a process tool 304 and a factory interface 306 coupled to process tool 304. Process tool 304 may include a housing 308 having a transfer chamber 310 therein. Transfer chamber 310 may include one or more processing chambers (also referred to as process chambers) 314, 316, 318 disposed therearound and coupled thereto. Processing chambers 314, 316, 318 may be coupled to transfer chamber 310 through respective ports, such as slit valves or the like. Transfer chamber 310 may also include a transfer chamber robot 312 configured to transfer substrate 302 between process chambers 314, 316, 318, load lock 320, etc. Transfer chamber robot 312 may include one or multiple arms where each arm includes one or more end effectors at the end of each arm. The end effector may be configured to handle particular objects, such as wafers.

Processing chambers 314, 316, 318 may be adapted to carry out any number of processes on substrates 302. A same or different substrate process may take place in each processing chamber 314, 316, 318. A substrate process may include atomic layer deposition (ALD), physical vapor deposition (PVD), chemical vapor deposition (CVD), etching, annealing, curing, pre-cleaning, metal or metal oxide removal, or the like. In some embodiments, a substrate process may include a combination of two or more of atomic layer deposition (ALD), physical vapor deposition (PVD), chemical vapor deposition (CVD), etching, annealing, curing, pre-cleaning, metal or metal oxide removal, or the like. Other processes may be carried out on substrates therein. Processing chambers 314, 316, 318 may each include one or more sensors configured to capture data for substrate 302 and/or an environment within processing chamber 314, 316, 318, before, after, or during a substrate process. In some embodiments, the one or more sensors may be configured to capture spectral data and/or non-spectral data for a portion of substrate 302.

A load lock 320 may also be coupled to housing 308 and transfer chamber 310. Load lock 320 may be configured to interface with, and be coupled to, transfer chamber 310 on one side and factory interface 306. Load lock 320 may have an environmentally-controlled atmosphere that may be changed from a vacuum environment (wherein substrates may be transferred to and from transfer chamber 310) to an inert-gas environment at or near atmospheric-pressure (wherein substrates may be transferred to and from factory interface 306) in some embodiments.

Factory interface 306 may be any suitable enclosure, such as, e.g., an Equipment Front End Module (EFEM). Factory interface 306 may be configured to receive substrates 302 from substrate carriers 322 (e.g., Front Opening Unified Pods (FOUPs)) docked at various load ports 324 of factory interface 306. A factory interface robot 326 (shown dotted) may be configured to transfer substrates 302 between substrate carriers (also referred to as containers) 322 and load lock 320. In other and/or similar embodiments, factory interface 306 may be configured to receive replacement parts from replacement parts storage containers 322.

Manufacturing system 300 may also be connected to a client device (not shown) that is configured to provide information regarding manufacturing system 300 to a user (e.g., an operator). In some embodiments, the client device may provide information to a user of manufacturing system 300 via one or more graphical user interfaces (GUIs). For example, the client device may provide information regarding one or more modifications to be made to a process recipe for a substrate 302 via a GUI.

Manufacturing system 300 may also include a system controller 328. System controller 328 may be and/or include a computing device such as a personal computer, a server computer, a programmable logic controller (PLC), a microcontroller, and so on. System controller 328 may include one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. System controller 328 may include a data storage device (e.g., one or more disk drives and/or solid state drives), a main memory, a static memory, a network interface, and/or other components. System controller 328 may execute instructions to perform any one or more of the methodologies and/or embodiments described herein. In some embodiments, system controller 328 may execute instructions to perform one or more operations at manufacturing system 300 in accordance with a process recipe. The instructions may be stored on a computer readable storage medium, which may include the main memory, static memory, secondary storage and/or processing device (during execution of the instructions).

System controller 328 may receive data from sensors included on or within various portions of manufacturing system 300 (e.g., processing chambers 314, 316, 318, transfer chamber 310, load lock 320, etc.). Data received by the system controller 328 may include spectral data and/or non-spectral data for a portion of substrate 302. For purposes of the present description, system controller 328 is described as receiving data from sensors included within processing chambers 314, 316, 318. However, system controller 328 may receive data from any portion of manufacturing system 300 and may use data received from the portion in accordance with embodiments described herein. In an illustrative example, system controller 328 may receive spectral data from one or more sensors for processing chamber 314, 316, 318 before, after, or during a substrate process at the processing chamber 314, 316, 318. Data received from sensors of the various portions of manufacturing system 300 may be stored in a data store 350. Data store 350 may be included as a component within system controller 328 or may be a separate component from system controller 328. In some embodiments, data store 350 may be data store 140 described with respect to FIG. 1.

Manufacturing system 300 may further include a substrate measurement subsystem 340. Substrate measurement subsystem 340 may obtain spectra measurements for one or more portions of a substrate 302 before or after the substrate 302 is processed at manufacturing system 300. In some embodiments, substrate measurement subsystem 340 may obtain spectra measurements for one or more portions of substrate 302 in response to receiving a request for the spectra measurements from system controller 328. Substrate measurement subsystem 340 may be integrated within a portion of manufacturing system 300. In some embodiments, substrate measurement subsystem 340 may be integrated within factory interface 306. In other or similar embodiments, substrate measurement subsystem 340 may not be integrated with any portion of manufacturing system 300 and instead may be a stand-alone component. In such embodiments, a substrate 302 measured at substrate measurement subsystem 340 may be transferred to and from a portion of manufacturing system 300 prior to or after the substrate 302 is processed at manufacturing system 300.

Substrate measurement subsystem 340 may obtain spectra measurements for a portion of substrate 302 by generating spectral data and/or spectral for the portion of substrate 302. In some embodiments, substrate measurement subsystem 340 is configured to generate spectral data, non-spectral data, positional data, and other substrate property data for substrate 302 (e.g., a thickness of substrate 302, a width of substrate 302, etc.). After generating data for substrate 302, substrate measurement subsystem 340 may transmit the generated data to system controller 328. Responsive to receiving data from substrate measurement subsystem 340, system controller 328 may store the data at data store 350.

FIG. 4 is a cross-sectional schematic side view of a substrate measurement subsystem 400, according to aspects of the present disclosure. Substrate measurement subsystem 400 may be configured to obtain measurements for one or more portions of a substrate, such as substrate 302 of FIG. 3, prior to or after processing of substrate 302 at a processing chamber. Substrate measurement subsystem 400 may obtain spectra measurements for a portion of substrate 302 by generating data (e.g., spectral data, non-spectral data, etc.) associated with the portion of substrate 302. In some embodiments, substrate measurement subsystem 400 may be configured to generate spectral data, non-spectral data, positional data, and/or other property data associated with substrate 302. Substrate measurement subsystem 400 may include a controller 430 configured to execute one or more instructions for generating data associated with a portion of substrate 302.

Substrate measurement subsystem 400 may detect that substrate 302 has been transferred to substrate measurement subsystem 400. Responsive to detecting that substrate 302 has been transferred to substrate measurement subsystem 400, substrate measurement subsystem 400 may determine a position and/or an orientation of substrate 302. The position and/or orientation of substrate 302 may be determined based on an identification of a reference location of substrate 302. A reference location may be a portion of substrate 302 that includes an identifying feature that is associated with a specific portion of substrate 302. Controller 328 may determine an identifying feature associated with a specific portion of substrate 302 based on determined identifying information for substrate 302.

Controller 430 may identify the reference location for substrate 302 using one or more camera components 450 configured to capture image data for substrate 302. Camera components 450 may generate image data for with one or more portions of the substrate 302 and transmit the image data to controller 430. Controller 430 may analyze the image data to identify an identifying feature associated with a reference location for substrate 302. Controller 430 may further determine a position and/or orientation of substrate 302 as depicted in the image data based on the identified identifying feature of substrate 302. Controller 430 may determine a position and/or orientation of substrate 302 based on the identified identifying feature of substrate 302 and the determined position and/or orientation of substrate 302 as depicted in the image data. Responsive to determining the position and/or orientation of substrate 302, controller 430 may generate positional data associated with one or more portions of substrate 302. In some embodiments, the positional data may include one or more coordinates (e.g., Cartesian coordinates, polar coordinates, etc.) each associated with a portion of substrate 302, where each coordinate is determined based on a distance from the reference location for substrate 302

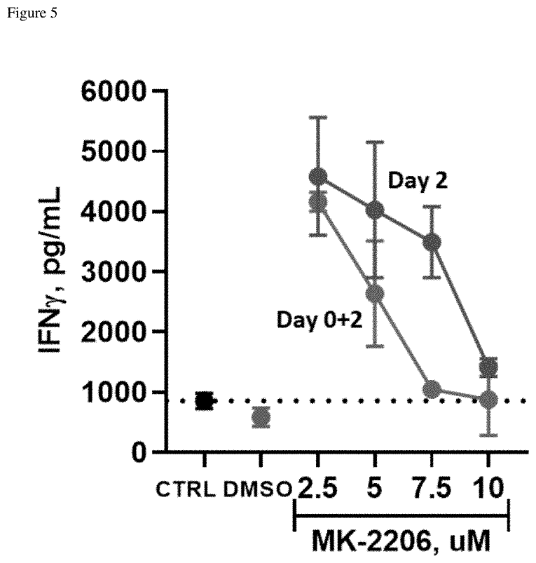

Substrate measurement subsystem 400 may include one or more measurement components for measuring substrate 302. In some embodiments, substrate measurement subsystem 400 may include one or more spectra sensing components 420 configured to generate spectral data for one or more portions of substrate 302. As discussed previously, spectral data may correspond to an intensity (i.e., a strength or amount of energy) of a detected wave of energy for each wavelength of the detected wave. Further details regarding the collected spectral data is provided with respect to FIG. 5.

A spectra sensing component 420 may be configured to detect waves of energy reflected from a portion of substrate 302 and generate spectral data associated with the detected waves. Spectra sensing component 420 may include a wave generator 422 and a reflected wave receiver 424. In some embodiments, wave generator 422 may be a light wave generator configured to generate a beam of light towards a portion of substrate 302. In such embodiments, reflected wave receiver 424 may be configured to receive a reflected light beam from the portion of substrate 302. Wave generator 422 may be configured to generate an energy stream 426 (e.g., a light beam) and transmit energy stream 426 to a portion of substrate 302. A reflected energy wave 428 may be reflected from the portion of substrate 302 and received by reflected wave receiver 424. Although FIG. 3A illustrates a single energy wave reflected off the surface of substrate 302, multiple energy waves may be reflected off the surface of substrate 302 and received by reflected wave receiver 424.

Responsive to reflected wave receiver 424 receiving reflected energy wave 428 from the portion of substrate 302, spectra sensing component 420 may measure a wavelength of each wave included in reflected energy wave 428. Spectra sensing component 420 may further measure an intensity of each measured wavelength. Responsive to measuring each wavelength and each wavelength intensity, spectra sensing component 420 may generate spectral data for the portion of substrate 302. Spectra sensing component 420 may transmit the generated spectral data to controller 430. Controller 430 may, responsive to receiving the generated spectral data, generate a mapping between the received spectral data and positional data for the measured portion of substrate 302.

Substrate measurement subsystem 400 may be configured to generate a specific type of spectral data based on a type of measurement to be obtained at substrate measurement subsystem 400. In some embodiments, spectra sensing component 420 may be a first spectra sensing component that is configured to generate one type of spectral data. For example, spectra sensing component 420 may be configured to generate reflectometry spectral data, ellipsometry spectral data, hyperspectral imaging data, chemical imaging data, thermal spectral data, or conductive spectral data. In such embodiments, the first spectra sensing component may be removed from substrate measurement subsystem 400 and replaced with a second spectra sensing component configured to generate a different type of spectral data (e.g., reflectometry spectral data, ellipsometry spectral data, hyperspectral imaging data, chemical imaging data, eddy current spectral data, thermal spectral data, or conductive spectral data).

In some embodiments, one or more measurement components, such as spectra sensing component 420, may be stationary components within substrate measurement subsystem 400. In such embodiments, substrate measurement subsystem 400 may include one or more positional components 440 configured to modify a position and/or an orientation of substrate 302 with respect to spectra sensing component 420. In some embodiments, positional components 440 may be configured to translate substrate 302 along a first axis and or a second axis, relative to spectra sensing component 420. In other or similar embodiments, positional components 440 may be configured to rotate substrate 302 around a third axis relative to spectra sensing component 420.

As spectra sensing component 420 generates spectral data for one or more portions of substrate 302, positional components 440 may modify the position and/or orientation of substrate 302 in accordance with the one or more determined portions to be measured for substrate 302. For example, prior to spectra sensing component 420 generating spectral data for substrate 302, positional components 440 may position substrate 302 at Cartesian coordinate (0,0) and spectra sensing component 420 may generate first spectral data for substrate 302 at Cartesian coordinate (0,0). Responsive to spectra sensing component 420 generating first spectral data for substrate 302 at Cartesian coordinate (0,0), positioning components 440 may translate substrate 302 along a first axis so that spectra sensing component 420 is configured to generate second spectral data for substrate 302 at Cartesian coordinate (0,1). Responsive to spectra sensing component 420 generating second spectral data for substrate 302 at Cartesian coordinate (0,1), controller 430 may rotate substrate 302 along a second axis so that spectra sensing component 420 is configured to generate third spectral data for substrate 302 at Cartesian coordinate (1,1). This process may occur multiple times until spectral data is generated for each determined portion of substrate 302.

In some embodiments, one or more layers 412 of material may be included on a surface of substrate 302. The one or more layers 412 may include etch material, photoresist material, mask material, deposited material, etc. In some embodiments, the one or more layers 412 may include an etch material to be etched according to an etch processed performed at a processing chamber. In such embodiments, spectral data may be collected for one or more portions of the un-etched etch material of the layer 412 deposited on substrate 302, in accordance with previously disclosed embodiments. In other or similar embodiments, the one or more layers 412 may include an etch material that has already been etched according an etch process at the processing chamber. In such embodiments, one or more structural features (e.g., lines, columns, openings, etc.) may be etched into the one or more layers 412 of substrate 302. In such embodiments, spectral data may be collected for one or more structural features etched into the one or more layers 412 of substrate 302.

Responsive to receiving at least one of the spectral data, the positional data, or the property data for the substrate 302, controller 430 may transmit the received data to system controller 328 for processing and analysis, in accordance with embodiment described herein.

FIG. 5 illustrates spectral data 500 collected for a substrate, according to aspects of the present disclosure. Spectral data may be generated from reflected energy received by the substrate measurement subsystem 400 of FIG. 4 or a sensor of a processing chamber, such as processing chamber 314, 316, 318 of FIG. 3, according to aspects of the present disclosure. As illustrated, multiple wave lengths may be included in reflected energy waves received by substrate measurement subsystem 400. Each reflected energy wave may be associated with a different portion of substrate 302. In some embodiments, an intensity may be measured for each reflected energy wave received by substrate measurement subsystem 400. As seen in FIG. 5, each intensity can be measured for each wavelength of reflected energy waves received by substrate measurement subsystem 400. The association between each intensity and each wavelength can be the basis for the formation of spectral data 500. In some embodiments, one or more wavelengths can be associated with an intensity value that is outside of an expected range of intensity values. For example, line 510 can be associated with an intensity value that is outside of the expected range of intensity values, as illustrated by lines 520. In such embodiments, the intensity value that is outside of the expected range of intensity values can be an indication that a defect exists at a portion of substrate 302. A modification may be made to a process recipe for substrate 302 based on the indication of the defect at the portion of substrate 302, in accordance with previously described embodiments.

FIG. 6 is a flow chart of a method 600 for estimating a metrology value for a profile of a substrate using a machine learning model, according to aspects of the present disclosure. Method 600 is performed by processing logic that may include hardware (circuitry, dedicated logic, etc.), software (such as is run on a general purpose computer system or a dedicated machine), firmware, or some combination thereof. In some embodiments, method 600 may be performed using predictive server 112 and trained machine learning model 190 of FIG. 1. In other or similar embodiments, one or more blocks of FIG. 6 may be performed by one or more other machines not depicted in FIG. 1.

At block 610, processing logic receives spectral data for a substrate being processed at a manufacturing system. In some embodiments, the spectral data can be received from a substrate measurement subsystem or another portion of the manufacturing system, in accordance with previously described embodiments.

At block 620, processing logic provides the spectral data for the substrate as input to a trained machine learning model. At block 630, processing logic obtains outputs from the machine learning model. At block 640, processing logic extracts confidence data from the outputs obtained at block 630. In some embodiments, the confidence data includes a level of confidence that a profile of the substrate is associated with a metrology value. In one example, the level of confidence is a real number between 0 and 1 inclusive. It should be noted that the level of confidence may not be a probability. For example, the sum of the confidence levels for all metrology values may not equal 1.

At block 650, processing logic uses confidence data to estimate a metrology value for the substrate being processed at the manufacturing system. In some embodiments, if the level of confidence for a metrology value satisfies a threshold condition, then a substrate is identified as being associated with the metrology value. At block 660, processing logic optionally provides an indication of the estimated metrology value to a user of the manufacturing system.

In some embodiments, one or more sensors included in portions of the manufacturing system can be the same type, or a similar type, of sensors as sensors included in another portion of the manufacturing system. For example, one or more sensors included in a substrate measurement sub-system that are configured to generate spectral data for a substrate are the same type, or a similar type, of sensors included in a processing chamber that are also configured to generate spectral data for the substrate. In such embodiments, the machine learning model can be trained using spectral data generated for sensors in either the substrate measurement sub-system or the processing chamber, in accordance with previously described embodiments. Spectral data collected from either the substrate measurement sub-system or the processing chamber may be used as training inputs to the trained machine learning model. Outputs from the trained machine learning model may be used to extract a metrology measurement value associated with a substrate, in accordance with previously described embodiments. As such, in some embodiments, a machine learning model trained using spectral data collected from a substrate measurement sub-system may be used to determine metrology measurement values using the input spectral data obtained from a processing chamber.

FIGS. 7A-7C illustrate an example GUI 700 for providing an indication of a metrology measurement for a portion of a substrate, according to aspects of the present disclosure. In some embodiments, GUI 700 may be displayed to a user of the manufacturing system via a client device of the manufacturing system.

GUI 700 may include a first portion 710 which displays one or more interactive components. First portion 710 may include a chamber selection component that enables a user to select an identifier of a processing chamber of the manufacturing system. Data for a substrate processed at a selected chamber may be displayed via other portions of GUI 700, responsive to the processing chamber identifier being selected. In some embodiments, the chamber selection component can include a drop down menu that provides a list of one or more processing chambers of the manufacturing system that are available for user selection. In other or similar embodiments, the chamber selection component can include any other type of component that may facilitate a user selection of a processing chamber identifier.

First portion 710 may further include a recipe selection component that enables a user to select an identifier of an operation of a substrate process recipe. Data associated with a selected operation of the process recipe may be displayed via the other portions of GUI 700, responsive to the operation identifier being selected. In some embodiments, the recipe selection component can include a drop down menu that provides a list of one or more process recipe operations that are available for user selection. In other or similar embodiments, the recipe selection component can include any other type of component that may facilitate a user selection of an operation identifier.

First portion 710 may further include a time period selection component that enables a user to select a time period for a process performed at the manufacturing system. Data associated with a substrate processed at the manufacturing system within the selected time period may be displayed via the other portions of GUI 700, responsive to the time period being selected. In some embodiments, the time period selection component can include a calendar component that provides a calendar indicating a certain date and/or time that a substrate process was performed at the manufacturing system. A user of the manufacturing system can select a first date and/or time and a second date and/or time via time period selection component of the first portion 710 of GUI 700. The selected first date and/or time and the selected second date and/or time may define the selected time period. In other or similar embodiments, the time period selection component can include any other type of component that may facilitate a user selection of time period.

First portion 710 may further include one or more additional components to enable a user to select or provide additional settings associated with a process performed at the manufacturing system. For example, first portion 710 may include a lower control limit component and/or an upper control limit component that enables a user to provide a lower control limit and/or an upper control limit associated with a process. In another example, first portion 710 may include a threshold component that enables a user to provide a threshold associated with a process. Any other type of component that may facilitate a user selecting or providing additional settings associated with a process may be included in first portion 710.

GUI 700 may further include a second portion 712 that provides metrology data associated with a substrate processed at the manufacturing system. In some embodiments, the metrology data can be associated with two or more substrates processed at the manufacturing system. In such embodiments, the metrology data can be displayed in a graphical formation, such as a graph illustrated with respect to FIG. 7. In other or similar embodiments, the metrology data can be displayed in any other formation that is suitable for displaying metrology data.

GUI 700 may further include a second portion 714 that provides a contour map associated with a substrate processed at the manufacturing system. The contour map may provide a user with a visual indication of one or more metrology measurements for a portion of a substrate. For example, the contour map can provide a user with a visual indication of a film thickness or an etch rate associated with a substrate.

In some embodiments, various types of substrates may be processed at the manufacturing system. For example, a blanket wafer or a patterned wafer may be processed at the manufacturing system. GUI 700 may provide one or more windows to display data associated with each different type of substrate processed at the manufacturing system. A third portion of GUI 700 may include a window selector 716 that facilitates transition between different windows displayed via GUI 700. A user may select an option via window selector 716 to cause a different window associated with a type of substrate to be displayed via GUI 700. For example, data associated with a blanket wafer may be displayed via GUI 700 responsive to a user selecting a “blanket” option of window selector 716, as illustrated in FIG. 7A. Data associated with a patterned wafer may be displayed via GUI 700 responsive to a user selecting a “patterned” option of window selector 716.

In some embodiments, different types of metrology data may be displayed to a user via GUI 700, depending on a selected option of window selector 716. As illustrated in FIG. 7B, responsive to a user selecting a “patterned” option of window selector 716, data associated with one or more patterned wafers processed at the manufacturing system is provided. In some embodiments, data associated with a critical dimension (referred to as a CD Index) of one or more substrates may be displayed via the second portion 712 of GUI 700, responsive to a user selecting a “patterned” option of window selector 716. In other or similar embodiments, data associated with another metrology measurement (e.g., etch rate, etch rate uniformity, critical dimension uniformity, edge to edge placement error, etc.) may be displayed via the second portion of 812.

In some embodiments, a user may view data used to generate one more components of GUI 700 (e.g., a graph provided in second portion 712) by selecting the “raw data” option of window selector 716. As illustrated in FIG. 7C, responsive to a user selecting a “raw data” option of window selector 716, raw data 720 associated one or more substrates processed at the manufacturing system may be provided. The raw data 720 may include a timestamp of when a measurement was generated for the substrate, an identifier of a lot including the substrate, an identifier of the substrate, an operation of a process recipe for the substrate, an identifier of a loop (i.e., two or more repeating operations) of a process recipe, positional data associated with the substrate, and a model thickness of the substrate.

In some embodiments, the first portion 710 of GUI 700 may be displayed regardless of the window provided via GUI 700. In other or similar embodiments, the first portion 710 may not be displayed for various windows provided by GUI 700.

FIG. 8 is a flow chart of a method 800 for generating training data for training a machine learning model, according to aspects of the present disclosure. FIG. 10 is a flow chart of a method 1000 for determining metrology measurement values for substrates at a manufacturing system, according to aspects of the present disclosure. FIG. 11 is a flow chart of another method 1100 for determining metrology measurement values for substrates at a manufacturing system, according to aspects of the present disclosure. Method 800, 1000, and/or 1100 may be performed by processing logic that may include hardware (circuitry, dedicated logic, etc.), software (such as is run on a general purpose computer system or a dedicated machine), firmware, or some combination thereof. In some embodiments, method 800, 1000, and/or 1100 may be performed by training set generator 172 of FIG. 1. In other or similar embodiments, one or more blocks of FIG. 8, 10, or 11 may be performed by one or more other machines not depicted in FIG. 1.

As indicated above, FIG. 8 is a flow chart of a method 800 for generating training data for training a machine learning model. At block 810, processing logic obtains spectral data associated with a first portion of a first prior substrate at a manufacturing system and at least one of a second portion of the first prior substrate or a third portion of a second prior substrate at the manufacturing system. The first prior substrate and/or the second prior substrate can correspond to a substrate 302, described herein. In some embodiments, the spectral data can be collected by substrate measurement subsystem 400, as described above. The spectral data can be collected according to other techniques, in additional or alternative embodiments.

At block 820, processing logic identifies metrology measurement values obtained for at least one of the second portion of the first prior substrate or the third portion of the second prior substrate. In some embodiments, metrology measurement values can be obtained using metrology equipment 128 for the second portion of the first prior substrate and/or the third portion of the second prior substrate, but not the first portion of the first prior substrate. FIG. 9 illustrates an example substrate 910 and one or more portions of substrate 910, according to aspects of the present disclosure. In an illustrative example, metrology measurement values can generated (e.g., by metrology equipment 128) at portion 912A, 914A, and/or at other portions of substrate 910 (e.g., at portion 916, at one or more of portions 918, etc.). Processing logic can determine metrology measurement values for other portions of substrate 910, such as portion 912B, 914B, 920, etc., and/or at portions of another substrate, in accordance with embodiments and examples provided below.

Referring back to FIG. 8, at block 830, processing logic determines a metrology measurement value associated with the first portion of the first prior substrate based on the identified one or more metrology measurement values. A metrology measurement value for portions of a substrate located at a particular radial distance from a center point of the substrate can correspond to (e.g., be the same as or similar to) metrology measurement values for other portions of the substrate associated with the particular radial distance from the center point. A radial distance refers a distance between a center point of a circular (or approximately circular) shaped object and another point of the circular (or approximately circular) shaped object (e.g., that is not at the center point). In some embodiments, processing logic can determine the metrology measurement value associated with the first portion of the first prior substrate based on metrology measurement values generated at portions located at the same or a similar radial distance from a center of the first prior substrate.

In an illustrative example, portion 916 of substrate 910 can be at or proximate to a center point of substrate 910. Portion 912A of substrate 910 can be located at a first radial distance 922A from portion 916. In some embodiments, spectral data can be generated at portion 912B of substrate 910, as described above. A metrology measurement value may not be generated for portion 912B. Processing logic can determine that portion 912B of substrate 910 is also located at or around the first radial distance 922A from portion 916. Accordingly, processing logic can determine that the metrology measurement value for portion 912B corresponds to (e.g., is the same as or approximately the same as) the metrology measurement value generated for portion 912A. In another illustrative example, portion 914A of substrate 910 can be located at a second radial distance 922B from portion 916. Processing logic can determine that portion 914B is also located at or around second radial distance 922B from portion 916. Accordingly, processing logic can determine that the metrology measurement value for portion 914B corresponds to the metrology measurement value for portion 914A.

In additional or alternative embodiments, processing logic can determine the metrology measurement value associated with the first portion of the first prior substrate based on one or more outputs of a function, in accordance with embodiments of FIG. 10. As described above, FIG. 10 is a flow chart of a method 1000 for determining metrology measurement values for substrates at a manufacturing system, according to aspects of the present disclosure. At block 1010, processing logic determines first coordinates associated with a first portion of a first substrate and second coordinates associated with a second portion of the first substrate and/or a third portion of a second substrate. In some embodiments, processing logic can determine the first coordinates and/or the second coordinates based on positional data collected by substrate measurement subsystem 400, as described above. The coordinates can include Cartesian coordinates, polar coordinates, and so forth.

At block 1020, processing logic can provide an indication of the first coordinates, the second coordinates, and the metrology measurement values obtained for at least one of the second portion of the first prior substrate or the third portion of the second prior substrate as input to a function. The function can include a linear interpolation function, an extrapolation function, a nearest-neighbor interpolation function, a Euclidean distance function, and so forth. At block 1030, processing logic can obtain one or more outputs of the function. The one or more outputs can include an indication of the metrology measurement value associated with the first portion of the first prior substrate. At block 1040, processing logic determines the metrology measurement value associated with the first portion of the first prior substrate based on the obtained one or more outputs.

In an illustrative example, metrology equipment 128 can generate metrology data for portions 916 and/or one or more of portions 918 of substrate 910, in some embodiments. Substrate measurement subsystem 400 can generate spectral data for portion 916, one or more of portions 918, and/or portion 920, as described above. Processing logic can provide coordinates associated with portions 916, 918, and/or 920 as input to a linear interpolation function with the metrology measurement values generated for portions 916 and/or one or more portions 918. The linear interpolation function can interpolate the metrology measurement value for portion 920 based on the provided coordinates associated with portions 916, 918, and/or 920 and the metrology measurement values generated for portions 916 and/or one or more portions 918, in some embodiments. Accordingly, processing logic can determine the metrology measurement value associated with portion 920 based on one or more outputs of the linear interpolation function.

In yet additional or alternative embodiments, processing logic can determine the metrology measurement value associated with the first portion of the first prior substrate based on one or more outputs of a machine learning model, in accordance with embodiments of FIG. 11. As described above, FIG. 11 is a flow chart of another method 1100 for determining metrology measurement values for substrates at a manufacturing system, according to aspects of the present disclosure. At block 1110, processing logic can obtain contextual data associated with the first prior substrate. Contextual data can include one or more of, first coordinates associated with the first portion of the first prior substrate, a substrate process previously performed and/or to be performed for the first prior substrate, a time period during which the substrate process was performed or is to be performed, a time period during which the spectral data for the first portion of the first prior substrate was collected, an indication of one or more types of equipment associated with the substrate process, and so forth.

At block 1120, processing logic can provide spectral data associated with the first portion of the first prior substrate and the obtained contextual data as input to a machine learning model. In some embodiments, the machine learning model can be trained to predict, based on given spectral data and contextual data for prior substrates at the manufacturing system, metrology measurement values of the prior substrates. In some embodiments, the machine learning model can be trained using a data set including training inputs indicating spectral data and/or contextual data associated with a prior substrate at the manufacturing system. The data set can additionally or alternatively include target outputs for the training inputs, the target outputs indicating one or more metrology measurement values collected for the prior substrate. The machine learning model 190 may use one or more of support vector machine (SVM), Radial Basis Function (RBF), clustering, supervised machine learning, semi-supervised machine learning, unsupervised machine learning, k-nearest neighbor algorithm (k-NN), linear regression, random forest, neural network (e.g., artificial neural network), etc.

In an illustrative example, the training inputs of the data set can include spectral data and/or contextual data associated with the second portion of the first prior substrate and/or the third portion of the second prior substrate. The target outputs for the training inputs can include metrology measurement values generated for the second portion of the first prior substrate and/or the third portion of the second prior substrate.

At block 1130, processing logic can obtain one or more outputs of the machine learning model. The one or more outputs can include metrology data indicating one or more sets of metrology measurement values and, for each set of metrology measurement values, a level of confidence that a respective set of metrology measurement values corresponds to the first portion of the first prior substrate. At block 1140, processing logic extracts the metrology measurement value associated with the first portion of the first prior substrate from the one or more outputs. Processing logic can extract the metrology measurement value from the one or more outputs by identifying the respective set of metrology measurement values having a level of confidence that satisfies a confidence criterion (e.g., exceeds a confidence threshold value, etc.). The identified set of metrology measurement values can include the metrology measurement value for the first portion of the first prior substrate.

Referring back to FIG. 8, at block 840, processing logic can generate training data for training a machine learning model to predict metrology measurement values of a current substrate at the manufacturing system by performing operations of block 842 and/or block 844. At block 842, processing logic can generate a first training input including the spectral data associated with the first portion of the first prior substrate. At block 844, processing logic can generate a first target output for the first training input. The first target output includes the determined metrology measurement value associated with the first portion of the first prior substrate (e.g., determined according to embodiments described above). In additional or alternative embodiments, processing logic can generate a second training input including the spectral data associated with the at least one of the second portion of the first prior substrate and/or the third portion of the second prior substrate. Processing logic can generate a second target output for the second training input, the second target output including metrology measurement value(s) generated for with the at least one of the second portion of the first prior substrate and/or the third portion of the second prior substrate. At block 850, processing logic provides the training data to train the machine learning model on (i) a set of training inputs including the first training input (and/or the second training input) and (ii) a set of target outputs including the first target output (and/or the second target output.

As described above, the machine learning model, upon training, can be configured to predict metrology measurement values associated with current substrates at the manufacturing system based on given spectral data. In some embodiments, the machine learning model described with respect to FIG. 8 can be different from the machine learning model described with respect to FIG. 11 because the machine learning model of FIG. 11 is trained to predict metrology measurement values based on spectral data and contextual data associated with a prior substrate at the manufacturing system, whereas the machine learning model described with respect to FIG. 8 is trained to predict metrology measurement values based on spectral data (e.g., and not contextual data) associated with current substrates at the manufacturing system.

In some embodiments, a machine learning model can be trained to predict metrology measurement values for current substrates at a manufacturing system in accordance with embodiments of both FIG. 2 and FIG. 8. In some embodiments, weights of the trained machine learning model can be adjusted (e.g., by a developer, an engineer, an operator, etc. of a manufacturing system) based on a source of metrology measurement values used to train the model. For example, some metrology measurement values can be generated by metrology equipment 128, as described with respect to FIG. 2 and FIG. 8, while other metrology measurement values are determined according to embodiments described with respect to FIGS. 9-11. In some embodiments, weights of the trained machine learning model can be adjusted such that weights associated with the generated metrology measurement values are higher than weights associated with determined metrology measurement values.

FIG. 12 depicts a block diagram of an illustrative computer system 1200 operating in accordance with one or more aspects of the present disclosure. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 1200 may correspond to system controller 328 of FIG. 3 or controller 430 of FIG. 4.

The example computing device 1200 includes a processing device 1202, a main memory 1204 (e.g., read-only memory (ROM), flash memory, dynamic random access memory (DRAM) such as synchronous DRAM (SDRAM), etc.), a static memory 1206 (e.g., flash memory, static random access memory (SRAM), etc.), and a secondary memory (e.g., a data storage device 1228), which communicate with each other via a bus 1208.

Processing device 1202 may represent one or more general-purpose processors such as a microprocessor, central processing unit, or the like. More particularly, the processing device 1202 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1202 may also be one or more special-purpose processing devices such as an application specific integrated circuit (ASIC), a field programmable gate array (FPGA), a digital signal processor (DSP), network processor, or the like. Processing device 1202 may also be or include a system on a chip (SoC), programmable logic controller (PLC), or other type of processing device. Processing device 1202 is configured to execute the processing logic for performing operations and steps discussed herein.

The computing device 1200 may further include a network interface device 1222 for communicating with a network 1264. The computing device 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse), and a signal generation device 1220 (e.g., a speaker).

The data storage device 1228 may include a machine-readable storage medium (or more specifically a non-transitory computer-readable storage medium) 1224 on which is stored one or more sets of instructions 1226 embodying any one or more of the methodologies or functions described herein. Wherein a non-transitory storage medium refers to a storage medium other than a carrier wave. The instructions 1226 may also reside, completely or at least partially, within the main memory 1204 and/or within the processing device 1202 during execution thereof by the computer device 1200, the main memory 1204 and the processing device 1202 also constituting computer-readable storage media.

The computer-readable storage medium 1224 may also be used to store model 190 and data used to train model 190. The computer readable storage medium 1224 may also store a software library containing methods that call model 190. While the computer-readable storage medium 1224 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
obtaining spectral data associated with a first portion of a first prior substrate at a manufacturing system and at least one of a second portion of the first prior substrate or a third portion of a second prior substrate at the manufacturing system;
identifying one or more metrology measurement values obtained for the at least one of the second portion of the first prior substrate or the third portion of the second prior substrate;
determining a metrology measurement value associated with the first portion of the first prior substrate based on the identified one or more metrology measurement values;
generating training data for training a machine learning model to predict metrology measurement values of a current substrate at the manufacturing system, wherein generating the training data comprises:
generating a first training input comprising the spectral data associated with the first portion of the first prior substrate; and
generating a first target output for the first training input, the first target output comprising the determined metrology measurement value associated with the first portion of the first prior substrate; and
providing the training data to train the machine learning model on (i) a set of training inputs comprising the first training input and (ii) a set of target outputs comprising the first target output.

2. The method of claim 1, wherein determining the metrology measurement value associated with the first portion of the first prior substrate comprises:
providing, as input to a function, an indication of one or more first coordinates associated with the first portion of the first prior substrate, one or more second coordinates associated with at least one of the second portion of the first prior substrate or the third portion of the second prior substrate, and the one or more metrology measurement values measured for the at least one of the second portion of the first prior substrate or the third portion of the second prior substrate,
wherein the metrology measurement value associated with the first portion of the substrate is determined based on one or more outputs of the function.

3. The method of claim 2, wherein the function comprises at least one of a linear interpolation function, an extrapolation function, a nearest-neighbor interpolation function, or a Euclidean distance function.

4. The method of claim 1, wherein determining the metrology measurement value associated with the first portion of the substrate comprises:
providing the obtained spectral data associated with the first portion of the first prior substrate and contextual data associated with the first prior substrate as input to an additional machine learning model, wherein the additional machine learning model is trained to predict, based on given spectral data and contextual data for prior substrates at the manufacturing system, metrology measurement values of the prior substrates, and wherein the additional machine learning model is trained using a dataset comprising the spectral data associated with the at least one of the second portion of the first prior substrate or the third portion of the second prior substrate and the one or more metrology measurement values measured for at least one of the second portion of the first prior substrate or the third portion of the second prior substrate; and
extracting the metrology measurement value from one or more outputs of the additional machine learning model.

5. The method of claim 4, wherein the one or more outputs of the additional machine learning model comprise metrology data indicating one or more sets of metrology measurement values and, for each set of metrology measurement values, a level of confidence that a respective set of metrology measurement values corresponds to the first portion of the first prior substrate, and wherein extracting the metrology measurement value from the one or more outputs comprises:
identifying the respective set of metrology measurement values having a level of confidence that satisfies a confidence criterion, wherein the identified respective set of metrology measurement values includes the metrology measurement value.

6. The method of claim 4, wherein the contextual data associated with the first prior substrate comprises at least one of one or more first coordinates associated with the first portion of the first prior substrate, a substrate process performed for the first prior substrate, a time period during which the substrate process was performed for the first prior substrate, a time period during which the spectral data for the first portion of the first prior substrate was collected, or an indication of one or more types of equipment used to perform the substrate process.

7. The method of claim 1, wherein determining the metrology measurement value associated with the first portion of the first prior substrate comprises:
determining a first radial distance between a center portion of the first prior substrate and the first portion of the first prior substrate; and
determining a second radial distance between at least one of the center portion of the first prior substrate and the second portion of the first prior substrate or a center portion of the second prior substrate and the third portion of the second prior substrate,
responsive to determining that the first radial distance corresponds to the second radial distance, determining that the metrology measurement value associated with the first portion of the first prior substrate corresponds to at least one of the identified one or more metrology measurement values obtained for the at least one of the second portion of the first prior substrate or the third portion of the second prior substrate.

8. The method of claim 1, wherein generating the training data further comprises:
generating a second training input comprising the spectral data associated with the at least one of the second portion of the first prior substrate or the third portion of the second prior substrate; and
generating a second target output for the second training input, the second target output comprising the one or more metrology measurement values measured for the at least one of the second portion of the first prior substrate or the third portion of the second prior substrate,
wherein the set of training inputs further comprises the second training input, and wherein the set of target outputs further comprises the second target output.

9. A system comprising:
a memory; and
a processing device coupled to the memory, the processing device to perform operations comprising:
obtaining spectral data associated with a first portion of a first prior substrate at a manufacturing system and at least one of a second portion of the first prior substrate or a third portion of a second prior substrate at the manufacturing system;
identifying one or more metrology measurement values obtained for the at least one of the second portion of the first prior substrate or the third portion of the second prior substrate;
determining a metrology measurement value associated with the first portion of the first prior substrate based on the identified one or more metrology measurement values;
generating training data for training a machine learning model to predict metrology measurement values of a current substrate at the manufacturing system, wherein generating the training data comprises:
generating a first training input comprising the spectral data associated with the first portion of the first prior substrate; and
generating a first target output for the first training input, the first target output comprising the determined metrology measurement value associated with the first portion of the first prior substrate; and
providing the training data to train the machine learning model on (i) a set of training inputs comprising the first training input and (ii) a set of target outputs comprising the first target output.

10. The system of claim 9, wherein determining the metrology measurement value associated with the first portion of the first prior substrate comprises:
providing, as input to a function, an indication of one or more first coordinates associated with the first portion of the first prior substrate, one or more second coordinates associated with at least one of the second portion of the first prior substrate or the third portion of the second prior substrate, and the one or more metrology measurement values measured for the at least one of the second portion of the first prior substrate or the third portion of the second prior substrate,
wherein the metrology measurement value associated with the first portion of the substrate is determined based on one or more outputs of the function.

11. The system of claim 10, wherein the function comprises at least one of a linear interpolation function, an extrapolation function, a nearest-neighbor interpolation function, or a Euclidean distance function.

12. The system of claim 9, wherein determining the metrology measurement value associated with the first portion of the substrate comprises:
providing the obtained spectral data associated with the first portion of the first prior substrate and contextual data associated with the first prior substrate as input to an additional machine learning model, wherein the additional machine learning model is trained to predict, based on given spectral data and contextual data for prior substrates at the manufacturing system, metrology measurement values of the prior substrates, and wherein the additional machine learning model is trained using a dataset comprising the spectral data associated with the at least one of the second portion of the first prior substrate or the third portion of the second prior substrate and the one or more metrology measurement values measured for at least one of the second portion of the first prior substrate or the third portion of the second prior substrate; and
extracting the metrology measurement value from one or more outputs of the additional machine learning model.

13. The system of claim 12, wherein the one or more outputs of the additional machine learning model comprise metrology data indicating one or more sets of metrology measurement values and, for each set of metrology measurement values, a level of confidence that a respective set of metrology measurement values corresponds to the first portion of the first prior substrate, and wherein extracting the metrology measurement value from the one or more outputs comprises:
identifying the respective set of metrology measurement values having a level of confidence that satisfies a confidence criterion, wherein the identified respective set of metrology measurement values includes the metrology measurement value.

14. The system of claim 12, wherein the contextual data associated with the first prior substrate comprises at least one of one or more first coordinates associated with the first portion of the first prior substrate, a substrate process performed for the first prior substrate, a time period during which the substrate process was performed for the first prior substrate, a time period during which the spectral data for the first portion of the first prior substrate was collected, or an indication of one or more types of equipment used to perform the substrate process.

15. The system of claim 9, wherein determining the metrology measurement value associated with the first portion of the first prior substrate comprises:
determining a first radial distance between a center portion of the first prior substrate and the first portion of the first prior substrate; and
determining a second radial distance between at least one of the center portion of the first prior substrate and the second portion of the first prior substrate or a center portion of the second prior substrate and the third portion of the second prior substrate,
responsive to determining that the first radial distance corresponds to the second radial distance, determining that the metrology measurement value associated with the first portion of the first prior substrate corresponds to at least one of the identified one or more metrology measurement values obtained for the at least one of the second portion of the first prior substrate or the third portion of the second prior substrate.

16. A non-transitory computer readable storage medium comprising instructions that, when executed by a processing device, cause the processing device to perform operations comprising:
obtaining spectral data associated with a first portion of a first prior substrate at a manufacturing system and at least one of a second portion of the first prior substrate or a third portion of a second prior substrate at the manufacturing system;
identifying one or more metrology measurement values obtained for the at least one of the second portion of the first prior substrate or the third portion of the second prior substrate;
determining a metrology measurement value associated with the first portion of the first prior substrate based on the identified one or more metrology measurement values;
generating training data for training a machine learning model to predict metrology measurement values of a current substrate at the manufacturing system, wherein generating the training data comprises:
generating a first training input comprising the spectral data associated with the first portion of the first prior substrate; and
generating a first target output for the first training input, the first target output comprising the determined metrology measurement value associated with the first portion of the first prior substrate; and
providing the training data to train the machine learning model on (i) a set of training inputs comprising the first training input and (ii) a set of target outputs comprising the first target output.

17. The non-transitory computer readable storage medium of claim 16, wherein determining the metrology measurement value associated with the first portion of the first prior substrate comprises:
providing, as input to a function, an indication of one or more first coordinates associated with the first portion of the first prior substrate, one or more second coordinates associated with at least one of the second portion of the first prior substrate or the third portion of the second prior substrate, and the one or more metrology measurement values measured for the at least one of the second portion of the first prior substrate or the third portion of the second prior substrate,
wherein the metrology measurement value associated with the first portion of the substrate is determined based on one or more outputs of the function.

18. The non-transitory computer readable storage medium of claim 17, wherein the function comprises at least one of a linear interpolation function, an extrapolation function, a nearest-neighbor interpolation function, or a Euclidean distance function.

19. The non-transitory computer readable storage medium of claim 16, wherein determining the metrology measurement value associated with the first portion of the substrate comprises:
providing the obtained spectral data associated with the first portion of the first prior substrate and contextual data associated with the first prior substrate as input to an additional machine learning model, wherein the additional machine learning model is trained to predict, based on given spectral data and contextual data for prior substrates at the manufacturing system, metrology measurement values of the prior substrates, and wherein the additional machine learning model is trained using a dataset comprising the spectral data associated with the at least one of the second portion of the first prior substrate or the third portion of the second prior substrate and the one or more metrology measurement values measured for at least one of the second portion of the first prior substrate or the third portion of the second prior substrate; and
extracting the metrology measurement value from one or more outputs of the additional machine learning model.

20. The non-transitory computer readable storage medium of claim 19, wherein the one or more outputs of the additional machine learning model comprise metrology data indicating one or more sets of metrology measurement values and, for each set of metrology measurement values, a level of confidence that a respective set of metrology measurement values corresponds to the first portion of the first prior substrate, and wherein extracting the metrology measurement value from the one or more outputs comprises:
identifying the respective set of metrology measurement values having a level of confidence that satisfies a confidence criterion, wherein the identified respective set of metrology measurement values includes the metrology measurement value.
